(19) United States
(12) Patent Application Publication
(10) Pub. No.: US 2015/0228829 A1
(43) Pub. Date: Aug. 13, 2015

(54) BLENDED POLYMER CONTAINING ETHYLENE/TETRAFLUOROETHYLENE COPOLYMER, MOLDED PRODUCT OF SUCH BLENDED POLYMER, BACK SHEET FOR SOLAR CELL, AND METHOD FOR PRODUCING THE MOLDED PRODUCT

(71) Applicant: Asahi Glass Company, Limited, Tokyo (JP)

(72) Inventors: Toshiaki SAWADA, Tokyo (JP); Seigo Kotera, Tokyo (JP); Tomoaki Nakanishi, Tokyo (JP)

(73) Assignee: Asahi Glass Company, Limited, Tokyo (JP)

(21) Appl. No.: 14/691,618

(22) Filed: Apr. 21, 2015

Related U.S. Application Data
(63) Continuation of application No. PCT/JP2013/084956, filed on Dec. 26, 2013.

(30) Foreign Application Priority Data
Dec. 27, 2012 (JP) 2012-284657

(51) Int. Cl. H01L 31/048; C08J 5/18

(52) U.S. Cl. CPC H01L 31/0481; C08J 5/18; C08J 2327/18; C08J 2333/12; C08J 2427/18; C08J 2433/12

(57) ABSTRACT

To provide a blended polymer containing an ethylene/tetrafluoroethylene copolymer, which is excellent in weather resistance and has a high thermal deformation temperature, a molded product such as a film thereof, a back sheet for a solar cell provided with such a film, etc., and a method for producing such a molded product. A blended polymer which comprises an ethylene/tetrafluoroethylene copolymer and a polymethyl methacrylate, wherein the mass ratio of the ethylene/tetrafluoroethylene copolymer to the total mass of the ethylene/tetrafluoroethylene copolymer and the polymethyl methacrylate, is from 50 to 75%, and which has a microphase-separated structure wherein the continuous phase is the ethylene/tetrafluoroethylene copolymer, and the dispersed phase is the polymethyl methacrylate.

### TECHNICAL FIELD

The present invention relates to a blended polymer containing an ethylene/tetrafluoroethylene copolymer, a molded product of such a blended polymer, a back sheet for a solar cell, and a method for producing the molded product.

### BACKGROUND ART

Fluororesins are excellent in solvent resistance, low-dielectric constant, low surface energy properties, non-adhesive properties, weather resistance, etc. and thus are used in various applications where general-purpose plastics cannot be used. Among them, an ethylene/tetrafluoroethylene copolymer (hereinafter referred to also as “ETFE”) is a fluororesin excellent in heat resistance, flame resistance, chemical resistance, weather resistance, low frictional properties, low dielectric constant, etc. and thus is used in a wide range of fields including e.g. a covering material for heat-resistant electric wires, a corrosion resistant piping material for chemical plants, a material for agricultural plastic green houses, a mold release film, etc. In recent years, however, in an application in the field of a back sheet for a solar cell or a covering material for a heat-resistant electric wire, a problem of thermal deformation at a high temperature is expected, and improvement in the thermal deformation temperature is required. With a view to e.g. improving the melt processability, it has heretofore been attempted to blend a polymethyl methacrylate (hereinafter referred to also as “PMMA”) to ETFE (e.g. Patent Document 1). Further, a melt-moldable polymer composition containing PMMA and a fluororesin, is also known (e.g. Patent Document 2).

### PRIOR ART DOCUMENTS

### Patent Documents

Patent Document 1: JP-A-60-72951
Patent Document 2: JP-A-2002-544359

### DISCLOSURE OF INVENTION

### Technical Problem

According to the present inventors, however, with the ETFE molded product as disclosed in Patent Document 1, it is not possible to sufficiently increase the glass transition temperature (Tg) of ETFE. Whereas, in Patent Document 2, there is no specific disclosure of ETFE as a fluororesin.

It is an object of the present invention to provide a blended polymer of an ethylene/tetrafluoroethylene copolymer and PMMA, which is excellent in weather resistance and has a high thermal deformation temperature, a molded product of such a blended polymer, a back sheet for a solar cell, which is provided with a film or sheet made of such a blended polymer, and a method for producing the molded product.

### Solution to Problem

The present invention provides a blended polymer, a molded product of such a blended polymer, a back sheet for a solar cell, provided with a film or sheet made of such a blended polymer, and a method for producing the molded product, having the following constructions [1] to [15].

[1] A blended polymer which comprises an ethylene/tetrafluoroethylene copolymer and a polymethyl methacrylate, wherein the mass ratio of the ethylene/tetrafluoroethylene copolymer to the total mass of the ethylene/tetrafluoroethylene copolymer and the polymethyl methacrylate, is from 50 to 75%, and which has a microphase-separated structure wherein the continuous phase is the ethylene/tetrafluoroethylene copolymer, and the dispersed phase is the polymethyl methacrylate.
[2] The blended polymer according to [1], wherein the viscosity-based volume ratio Rη represented by the following formula (1) is smaller than 1:

Rη=(η_{E}/η_{P})×(φ_{P}/φ_{E}) (1)

wherein η_{E} is the melt viscosity of the ethylene/tetrafluoroethylene copolymer at a melting temperature within a range of from 180 to 300° C., η_{P} is the melt viscosity of the polymethyl methacrylate at the same melting temperature as above, φ_{E} is the volume fraction of the ethylene/tetrafluoroethylene copolymer in the blended polymer at the same melting temperature as above, and φ_{P} is the volume fraction of the polymethyl methacrylate in the blended polymer at the same melting temperature as above.
[3] The blended polymer according to [2], wherein the viscosity-based volume ratio Rη is at least 0.4.
[4] The blended polymer according to any one of [1] to [3], wherein the glass transition temperature of the blended polymer is from 120 to 130° C.
[5] The blended polymer according to any one of [1] to [4], wherein the melt viscosity of the ethylene/tetrafluoroethylene copolymer is from 10 to 3,000 Pa·s at a measuring temperature of 270° C. and a shear rate of 608 s⁻¹.
[6] The blended polymer according to any one of [1] to [5], wherein the ethylene/tetrafluoroethylene copolymer is an ethylene/tetrafluoroethylene copolymer having a molar ratio of (constituent units based on tetrafluoroethylene)/(constituent units based on ethylene) of from 20/80 to 80/20.
[7] The blended polymer according to any one of [1] to [6], wherein the ethylene/tetrafluoroethylene copolymer has units based on a monomer other than ethylene and tetrafluoroethylene, and the ratio of such units is from 0.1 to 10 mol % to all units in the copolymer.
[8] The blended polymer according to [7], wherein the monomer other than ethylene and tetrafluoroethylene, is a perfluoro-olefin other than tetrafluoroethylene, a polyfluoroalkylethylene or a perfluoro vinyl ether.
[9] The blended polymer according to any one of [1] to [8], wherein the melt viscosity of the polymethyl methacrylate is from 300 to 450 Pa·s at a measuring temperature of 270° C. and a shear rate of 608 s⁻¹.
[10] A molded product made of the blended polymer as defined in any one of [1] to [9].
[11] The molded product according to [10], which is a film or sheet.
[12] A back sheet for a solar cell, which is provided with the film or sheet as defined in [11].
[13] A method for producing a molded product comprising an ethylene/tetrafluoroethylene copolymer and a polymethyl methacrylate, which comprises melt-kneading an ethylene/tetrafluoroethylene copolymer and a polymethyl methacrylate to form a melt-kneaded product so that the mass ratio of the ethylene/tetrafluoroethylene copolymer to the total mass of the ethylene/tetrafluoroethylene copolymer and the polymethyl methacrylate, would be from 50 to 75%, and the viscosity-based volume ratio Rη represented by the following formula (1) would be smaller than 1, and melt-molding the melt-kneaded product:

Rη=(η_{E}/η_{P})×(φ_{P}/φ_{E}) (1)

wherein η_{E} is the melt viscosity of the ethylene/tetrafluoroethylene copolymer at a melting temperature within a range of from 180 to 300° C., η_{P} is the melt viscosity of the polymethyl methacrylate at the same melting temperature as above, φE is the volume fraction of the ethylene/tetrafluoroethylene copolymer in the molded product at the same melting temperature as above, and φ_{P} is the volume fraction of the polymethyl methacrylate in the molded product at the same melting temperature as above.
[14] The method for producing a molded product according to [13], wherein the melt viscosity of the ethylene/tetrafluoroethylene copolymer is from 10 to 3,000 Pa·s at a measuring temperature of 270° C. and a shear rate of 608 s⁻¹.
[15] The method for producing a molded product according to [13] or [14], wherein the melt viscosity of the polymethyl methacrylate is from 300 to 450 Pa·s at a measuring temperature of 270° C. and a shear rate of 608 s⁻¹.

### Advantageous Effects of Invention

The blended polymer of the present invention and the molded product thereof are excellent in weather resistance and have a high thermal deformation temperature.

The back sheet for a solar cell, which is provided with a film or sheet made of the blended polymer of the present invention, is excellent in weather resistance, has a high thermal deformation temperature and is excellent in thermal deformation resistance.

### BRIEF DESCRIPTION OF DRAWINGS

FIG. 1 is a view showing an electron microscopic picture of the film produced in Example 1.

FIG. 2 is a view showing an electron microscopic picture of the film produced in Comparative Example 1.

### DESCRIPTION OF EMBODIMENTS

The blended polymer of the present invention is a blended polymer which comprises ETFE and PMMA, wherein the mass ratio of ETFE to the total mass of ETFE and PMMA in the blended polymer, is from 50 to 75%, and which has a microphase-separated structure wherein the continuous phase is ETFE, and the dispersed phase is PMMA.

In the microphase-separated structure of a blended polymer, usually, a microphase-separated structure appears in a solid state, and the blended polymer has a uniform structure in a molten state. The blended polymer having a microphase-separated structure in the present invention is meant for one in a solid state, but in this specification, a polymer mixture having a uniform molten state wherein a microphase-separated structure appears when it becomes to be in a solid state, may also be called a blended polymer.

Further, a melt-kneaded polymer mixture in the present invention may be referred to as a melt-kneaded product. The melt-kneaded product means not only one in a molten state but also one in a solidified state as cooled.

The above mass ratio of ETFE is preferably from 50 to 75%, more preferably from 50 to 65%. Further, the above mass ratio of PMMA is preferably from 25 to 50%, more preferably from 35 to 50%. Within these ranges, the blended polymer is excellent in weather resistance, has a high thermal deformation temperature and has high thermal deformation resistance.

### (ETFE)

In the present invention, ETFE has constituent units based on tetrafluoroethylene (hereinafter referred to as “TFE”) and constituent units based on ethylene. The molar ratio of constituent units based on TFE/constituent units based on ethylene is preferably from 20/80 to 80/20, more preferably from 30/70 to 70/30, most preferably from 40/60 to 60/40.

Further, ETFE may contain constituent units based on another monomer in addition to constituent units based on TFE and ethylene. Such another monomer may, for example, be a fluoroethylene (excluding TFE) such as CF₂═CFCl or CF₂═CH₂; a C₃₋₅ perfluoro-olefin such as hexafluoropropylene (hereinafter referred to as “HFP”) or octafluorobutene-1; a polyfluoroalkylethylene represented by X¹(CF₂)ₙCY═CH₂ (wherein each of X¹ and Y is a hydrogen atom or a fluorine atom, and n is an integer of from 2 to 8); a perfluoro vinyl ether such as R^{f}OCFX²(CF₂)ₘOCF═CF₂ (wherein R^{f} is a C₁₋₆ perfluoroalkyl group, X² is a fluorine atom or a trifluoromethyl group, and m is an integer of from 0 to 5); a perfluoro vinyl ether having a group readily convertible to a carboxylic group or sulfonic group, such as CH₃OC(═O)CF₂CF₂CF₂OCF═CF₂ or FSO₂CF₂CF₂OCF(CF₃)CF₂OCF═CF₂; a perfluoro vinyl ether having an unsaturated bond, such as CF₂═CFOCF₂CF═CF₂ or CF₂═CFO(CF₂)₂CF═CF₂; a fluorinated monomer having an alicyclic structure, such as perfluoro(2,2-dimethyl-1,3-dioxole), 2,2,4-trifluoro-5-trifluoromethoxy-1,3-dioxole or perfluoro(2-methylene-4-methyl-1,3-dioxolane); or an olefin (excluding ethylene) such as a C₃ olefin such as propylene, or a C₄ olefin such as butylene or isobutylene.

In the above polyfluoroalkylethylene represented by X¹(CF₂)ₙCY═CH₂, n is preferably from 2 to 6, more preferably from 2 to 4. Its specific examples may, for example, be CF₃CF₂CH═CH₂, CF₃(CF₂)₃CH═CH₂, CF₃(CF₂)₅CH═CH₂, CF₃CF₂CF₂CF═CH₂, CF₂HCF₂CF₂CF═CH₂, CF₂HCF₂CF₂CF═CH₂, etc.

Further, specific examples of the above perfluoro vinyl ether may, for example, be perfluoro(methyl vinyl ether), perfluoro(ethyl vinyl ether), perfluoro(propyl vinyl ether) (hereinafter referred to as “PPVE”), CF₂═CFOCF₂CF(CF₃)O(CF₂)₂CF₃, CF₂═CFO(CF₂)₃O(CF₂)₂CF₃, CF₂═CFO(CF₂CF(CF₃)O)₂(CF₂)₂CF₃, CF₂═CFOCF₂CF₂OCF₂CF₃ and CF₂═CFO(CF₂CF₂O)₂CF₂CF₃.

Another monomer is preferably the above polyfluoroalkylethylene, the perfluoro-olefin (other than TFE) such as HFP, or the perfluoro vinyl ether such as PPVE, more preferably HFP, PPVE, CF₃CF₂CH═CH₂ or CF₃(CF₂)₃CH═CH₂. Further, as such another monomer, one type may be used alone, or two or more types may be used in combination.

The proportion of constituent units based on such another monomer is preferably from 0.1 to 10 mol %, more preferably from 0.2 to 6 mol %, most preferably from 0.5 to 3 mol %, in all constituent units (100 mol %) in ETFE.

The melt viscosity of ETFE in the present invention is preferably from 10 to 3,000 Pa·s, more preferably from 50 to 1,000 Pa·s, most preferably from 100 to 700 Pa·s, at a measuring temperature of 270° C. and a shear rate of 608 s⁻¹.

Commercial products of ETFE may, for example, be Fluon manufactured by Asahi Glass Co., Ltd. and Neoflon manufactured by Daikin Industries, Ltd.

### (PMMA)

PMMA in the present invention is not particularly limited and may, for example, be a homopolymer of methyl methacrylate (MMA), or a copolymer of MMA with a small amount of an alkyl methacrylate (provided that MMA is excluded).

The melt viscosity of PMMA in the present invention is preferably from 300 to 450 Pa·s, more preferably from 350 to 450 Pa·s, most preferably from 350 to 400 Pa·s, at a measuring temperature of 270° C. and a shear rate of 608 s⁻¹.

Commercial products of PMMA may, for example, be ACRYPET manufactured by Mitsubishi Rayon Co., Ltd., DELPET manufactured by Asahi Kasei Chemicals Corporation and PARAPET manufactured by Kuraray Co., Ltd.

### (Blended Polymer and Method for Producing Molded Product)

The blended polymer of the present invention is produced by melt-kneading ETFE and PMMA so that the mass ratio of ETFE would be from 50 to 75% to the total mass of ETFE and PMMA. At that time, it is preferred to melt-knead ETFE and PMMA so that the viscosity-based volume ratio Rη represented by the following formula (1) would be smaller than 1. The melt-kneading is followed by molding to obtain a molded product of the blended polymer. Otherwise, a cooled blended polymer may be used as a molding material for melt-molding to produce a molded product of the blended polymer.

Further, the method for producing a molded product of the present invention is characterized by melt-kneading ETFE and PMMA to form a melt-kneaded product so that the mass ratio of ETFE to the total mass of ETFE and PMMA, would be from 50 to 75%, and the viscosity-based volume ratio Rη represented by the following formula (1) would be smaller than 1, and melt-molding the melt-kneaded product.

The melt-kneaded product obtained by melt-kneading is then subjected to molding to obtain a final molded product. Otherwise, it may be formed into a molded product having a shape of e.g. pellets, to be used as a molding material. Further, the melt-kneaded product obtained by melt-kneading may be cooled to obtain a solid-state melt-kneaded product, and such a solid state melt-kneaded product in a powder or massive form may be used as a molding material.

Rη=(η_{E}/η_{P})×(φ_{P}/φ_{E}) (1)

wherein η_{E} is the melt viscosity of ETFE at a melting temperature within a range of from 180 to 300° C., η_{P} is the melt viscosity of PMMA at the same melting temperature as above, φ_{E} is the volume fraction of ETFE in the ETFE molded product at the same melting temperature as above, and φ_{P} is the volume fraction of PMMA in the ETFE molded product at the same melting temperature as above.

The above melting temperature is a temperature at which the melt-kneaded product is in such a state as melted as a uniform mixture and such a temperature is within a range of from 180 to 300° C. All of φ_{E}, φ_{P}, φ_{P} and φ_{E} are values measured at the same temperature. Further, the above melting temperature is preferably a temperature which is the same as or substantially equal to the molding temperature at the time of melt-molding the melt-kneaded product. In Examples given hereinafter, 270° C. is adopted as the measuring temperature and the molding temperature.

Here, in the blended polymer, the volume fraction φ_{E} of ETFE, and the volume fraction φ_{P} of PMMA, are:

φ_{E}=V_{E}/V_{T},and φ_{P}=V_{P}/V_{T},

wherein V_{E} is the volume of ETFE in the blended polymer, V_{P} is the volume of PMMA in the blended polymer, and V_{T} is the volume of the blended polymer; and

V_{E}=W_{E}/ρ_{E},V_{P}=W_{P}/ρₚ,and V_{T}=(W_{E}+W_{P})/ρ_{T},

wherein W_{E} is the mass of ETFE in the blended polymer, W_{P} is the mass of PMMA in the blended polymer, ρ_{E} is the density of ETFE, ρ_{P} is the density of PMMA, and ρ_{T} is the density of the blended polymer.

Therefore, the above viscosity-based volume ratio Rη becomes:

$$\begin{matrix}R η = ( {η}_{E} / {η}_{P} ) \times ( {ϕ}_{P} / {ϕ}_{E} ) \\ = ( {η}_{E} / {η}_{P} ) \times \\ \{ ( {W}_{P} / {ρ}_{P} ) / ( ( {W}_{E} + {W}_{P} ) / {ρ}_{T} ) \} / \{ ( {W}_{E} / {ρ}_{E} ) / ( ( {W}_{E} + {W}_{P} ) / {ρ}_{T} ) \} \\ = ( {η}_{E} / {η}_{P} ) \times \{ ( {W}_{P} / {ρ}_{P} ) / ( {W}_{E} / {ρ}_{E} ) \} \\ = ( {W}_{P} \times {ρ}_{E} \times {η}_{E} ) / ( {W}_{E} \times {ρ}_{P} \times {η}_{P} )\end{matrix} \qquad ( 2 )$$

The blended polymer of the present invention forms a microphase-separated structure wherein an ETFE phase and a PMMA phase are mixed. When the viscosity-based volume ratio Rη is within the above range of smaller than 1, ETFE forms a continuous phase, and PMMA forms a dispersed phase.

The viscosity-based volume ratio Rη is more preferably at most 0.99. Further, the viscosity-based volume ratio Rη is preferably at least 0.4.

The formula (1) for the viscosity-based volume ratio Rη represents a ratio of the volume and melt viscosity ratios of ETFE and PMMA in the blended polymer obtained by melt-kneading ETFE and PMMA and in a molded product obtained by molding the blended polymer and is considered to be an index for predicting the phase structure. In a non-patent document (G. M. Jordhamo, J. A. Manson, and L. H. Sperling, Polym. Eng. Sci., 26, 517 (1986)), an empirical formula of the same type as the formula (1) is disclosed, and it is disclosed that a phase structure is predicted from the value obtained by the formula.

The above melt kneading of ETFE and PMMA is preferably conducted by using a small size batch mixer and a twin screw extruder. As a melt-kneading condition, the temperature is preferably from 180 to 300° C., more preferably from 180 to 280° C., most preferably from 230 to 270° C. The molding time is preferably from 5 to 60 minutes, more preferably from 5 to 30 minutes, most preferably from 5 to 20 minutes.

As mentioned above, the molten state melt-kneaded product obtained by melt-kneading is then subjected to molding to obtain a molded product. Otherwise, a molding material made of a blended polymer in a pellet, powder or massive form to be used as a molding material, may be molded to form a molded product. The production of a molded product is preferably melt-molding to mold a melt-kneaded product in a molten state. The melt-molding is preferably extrusion molding to produce a continuous molded product such as a film or sheet, or injection molding or press molding by means of a mold, die, etc.

In the melt-molding such as extrusion molding or injection molding, a molding material is melted and molded. At the time of such melting, it is common to knead the molding material while melting it. Accordingly, ETFE and PMMA can be mixed and melt-kneaded in a melt-molding device, and therefore, a molding material made of ETFE and a molding material made of PMMA may be introduced into the melt-molding device without preliminarily melt-kneading them, so that the melt-kneading is conducted in the melt-molding device, followed by molding to produce a molded product of the blended polymer.

The temperature condition in the melt-molding is preferably from 180 to 300° C., more preferably from 180 to 280° C., most preferably from 230 to 270° C. The molding time in the melt-molding is preferably from 5 to 60 minutes, more preferably from 5 to 30 minutes, most preferably from 5 to 20 minutes.

The molded product of the blended polymer is preferably a film or sheet. In the present invention, the film or sheet is meant for a molded product having substantially a constant thickness. The film is meant for one having a thickness of at most 0.2 mm, and the sheet is meant for one having a thickness exceeding 0.2 mm. However, a film or sheet in a commonly employed name such as a back sheet for a solar cell, is not necessarily limited to the above mentioned thickness.

The thickness of the film or sheet of the present invention is preferably from 1 to 800 μm, more preferably from 5 to 500 μm.

The molded product of the blended polymer is particularly preferably a film or sheet. The film or sheet made of the blended polymer of the present invention is suitable e.g. for use as a film for agriculture or a back sheet for a solar cell, which is required to have weather resistance.

The molding method for a film or sheet may, for example, be extrusion molding, inflation molding or injection molding, but extrusion molding is preferred.

### (Back Sheet for Solar Cell)

The back sheet for a solar cell of the present invention is provided with a film or sheet made of the blended polymer of the present invention.

Usually, as the back sheet for a solar cell of the present invention, a laminated film or laminated sheet, obtained by laminating a film or sheet made of the blended polymer of the present invention with e.g. polyethylene terephthalate (PET), is used.

### EXAMPLES

Now, the present invention will be described with reference to Examples, but it should be understood that the present invention is by no means limited to these Examples.

The method for producing a film (one example of the molded product of the blended polymer of the present invention) in each Example, and the thermal deformation resistance test and weather resistance test of the film, were conducted by the following methods. The tests of the film in each Comparative Example were also conducted in the same manner.

### (Viscosity-Based Volume Ratio)

The melt viscosity (η_{E}) of ETFE and the melt viscosity (η_{P}) of PMMA were measured at a shear rate of 608 s⁻¹ at 270° C. by means of a capillary rheometer (Capilograph manufactured by Toyo Seiki Seisakusho Ltd.) using a die with L/D=10 and φ1 mm. Further, the density (ρ_{E}) of ETFE and the density (ρ_{P}) of PMMA were measured by means of a specific gravity meter AUW-D-SGM220 manufactured by Shimadzu Corporation). The density measurement was conducted by using a film having a thickness of 0.1 mm prepared by pressing a sample by a mirror smoothly polished plate of 150 mm×150 mm at 270° C. under a pressure of 8.7 MPa for 10 minutes and cut out in a size of 20 mm×20 mm. By using such a viscosity and a density, and the mass (W_{E}) of ETFE and the mass (W_{P}) of PMMA employed, the viscosity-based volume ratio was calculated by the above-mentioned formula (2) as follows. The calculated results are shown in Table 2.

Viscosity-based volume ratio=(W_{P}×ρ_{E}×η_{E})/(W_{E}×ρ_{P}×η_{P})

### Production of Films in Examples and Comparative Examples

By means of a small size batch mixer (Laboplastomill manufactured by Toyo Seiki Seisakusho Ltd.), ETFE and PMMA were melt-kneaded in a ratio as shown in Table 1 to obtain a blended polymer. The blended polymer was pressed by a hot press machine (Mini Test Press MP-WCL manufactured by Toyo Seiki Seisakusho Ltd.) to prepare a film having a thickness of 0.1 mm. The conditions for melt-kneading were such that by using KF15V mixer, kneading was conducted at 270° C. at a rotational speed of 50 rpm for 10 minutes.

Further, the conditions for hot pressing were such that by using a mirror smoothly polished plate of 150 mm×150 mm, pressing was conducted at 270° C. at 8.7 MPa as pressure for 10 minutes.

Also in the cases of a combination of ETFE and PMMA in Comparative Examples 1 to 3 and 7 and a combination of ETFE and PC1 in Comparative Example 4, a film was prepared under the same conditions as in Examples. Further, an ETFE film and a PMMA film in Comparative Examples 5 and 6 were prepared under the same hot pressing conditions as in Examples.

Using the obtained film, the thermal deformation resistance test and weather resistance test as described later were conducted. In Table 2, together with the viscosity-based volume ratio, as the evaluation results, the glass transition temperature of the film and the strength retention rate after the weather resistance test, are shown.

### (Thermal Deformation Resistance Test)

The thermal deformation resistance was evaluated by the glass transition temperature of the film. The glass transition temperature was obtained from the peak of tan δ as a result of measurement of the dynamic viscoelasticity of the film. The dynamic viscoelasticity was measured by using a dynamic viscoelasticity measuring apparatus DVA-220 manufactured by IT Keisoku Seigyo K.K. in a temperature dispersion mode at a frequency of 10 Hz.

### (Weather Resistance Test)

The weather resistance test of the film was conducted as follows.

By means of a sunshine weather meter (manufactured by Suga Test Instruments Co., Ltd., an accelerated weathering deterioration test was conducted for 500 hours, whereby the ratio in tensile strength to a non-tested sample was obtained (shown as strength retention rate after weather resistance test in Table 2). The tensile test was conducted by means of a small size universal tester (Tensilon manufactured by A&D Co., Ltd.).

### [Materials Used]

ETFE 1: Aflon ETFE-C88AXMB MFR: 278, manufactured by Asahi Glass Co., Ltd., melt viscosity: 130 Pa·s (270° C.), density: 1.75

ETFE 2: Aflon ETFE-C88AXMB MFR: 169, manufactured by Asahi Glass Co., Ltd., melt viscosity: 260 Pa·s (270° C.), density: 1.75

ETFE 3: Aflon LMETFE-740AP, manufactured by Asahi Glass Co., Ltd., melt viscosity: 510 Pa·s (270° C.), density: 1.75

PMMA 1: Acrypet VH3, manufactured by Mitsubishi Plastics, Inc., melt viscosity: 280 Pa's (270° C.), density: 1.19

PMMA 2: Acrypet VH4, manufactured by Mitsubishi Plastics, Inc., melt viscosity: 350 Pa·s (270° C.), density: 1.19

PC 1 (polycarbonate resin): Calibre 301-10, manufactured by Sumika Styron Polycarbonate, Limited, melt viscosity: 820 Pa·s (270° C.), density: 1.20

The polymer compositions in Examples and Comparative Examples are shown in Table 1, and the results of measuring the respective physical properties are shown in Table 2.

TABLE 1

| | Type of | Mass % of | Type of | Mass % of |
|---|---|---|---|---|
| | ETFE | ETFE | resin 2 | resin 2 |
| Ex. 1 | ETFE 1 | 50 | PMMA 1 | 50 |
| Ex. 2 | ETFE 2 | 75 | PMMA 1 | 25 |
| Ex. 3 | ETFE 2 | 50 | PMMA 2 | 50 |
| Ex. 4 | ETFE 1 | 50 | PMMA 2 | 50 |
| Ex. 5 | ETFE 3 | 70 | PMMA 2 | 30 |
| Ex. 6 | ETFE 2 | 65 | PMMA 1 | 35 |
| Comp. Ex. 1 | ETFE 2 | 50 | PMMA 1 | 50 |
| Comp. Ex. 2 | ETFE 2 | 90 | PMMA 1 | 10 |
| Comp. Ex. 3 | ETFE 3 | 90 | PMMA 1 | 10 |
| Comp. Ex. 4 | ETFE 2 | 50 | PC1 | 50 |
| Comp. Ex. 5 | ETFE 2 | 100 | — | 0 |
| Comp. Ex. 6 | ETFE 3 | 100 | — | 0 |
| Comp. Ex. 7 | ETFE 2 | 80 | PMMA 2 | 20 |

TABLE 2

| | | Strength retention | Glass transition |
|---|---|---|---|
| | Viscosity-based | rate after weather | temperature (° C.) |
| | volume ratio | resistance test (%) | of film |
| Ex. 1 | 0.68 | 93 | 126 |
| Ex. 2 | 0.46 | 95 | 126 |
| Ex. 3 | 0.98 | 92 | 126 |
| Ex. 4 | 0.55 | 95 | 126 |
| Ex. 5 | 0.94 | 93 | 126 |
| Ex. 6 | 0.74 | 94 | 126 |
| Comp. Ex. 1 | 1.37 | 25 | 134 |
| Comp. Ex. 2 | 0.15 | 93 | 96 |
| Comp. Ex. 3 | 0.3 | 92 | 63 |
| Comp. Ex. 4 | 0.46 | 93 | 96 |
| Comp. Ex. 5 | — | 100 | 96 |
| Comp. Ex. 6 | — | 100 | 63 |
| Comp. Ex. 7 | 0.27 | 95 | 96 |

From Table 2, it is evident that in Examples 1 to 6, films excellent in weather resistance and also excellent in thermal deformation resistance are obtained. On the other hand, it is evident that in Comparative Example 1, the strength retention rate after the weather resistance test is low, and in Comparative Examples 2 to 7, the glass transition temperature is low i.e. the thermal deformation resistance is inadequate.

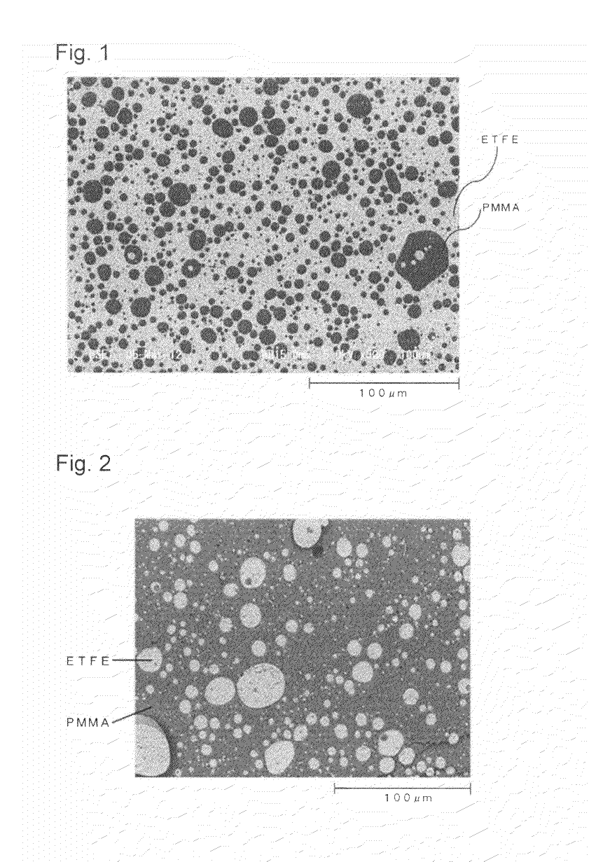

FIGS. 1 and 2 show electron microscopic pictures of the film prepared in Example 1 and the film prepared in Comparative Example 1, respectively. Here, the apparatus used for taking pictures is S-3000 manufactured by Hitachi High-Technologies Corporation.

As shown in FIG. 1, in the film prepared in Example 1, ETFE is a continuous phase, and PMMA is a dispersed phase. This is considered to be attributable to that as shown in Table 2, the viscosity-based volume ratio is smaller than 1. Whereas, in the film prepared in Comparative Example 1, PMMA is a continuous phase, and ETFE is a dispersed phase. With respect to the film prepared in Comparative Example 1, the reason for the strength retention rate after weather resistance test being low is considered to be such that in the combination in the mass ratio of ETFE 2 to PMMA being 50:50 in Comparative Example 1, the viscosity-based volume ratio becomes larger than 1 (1.37), and the film has a phase structure wherein PMMA i.e. not ETFE becomes a continuous phase.

Further, the reason for the thermal deformation resistance of the films prepared in Comparative Examples 2, 3 and 7 being low is considered to be such that the proportion of PMMA is small, and the reason for the thermal deformation resistance of the films prepared in Comparative Examples 4 to 6 being low is considered to be such that PMMA is not blended.

### INDUSTRIAL APPLICABILITY

The molded product of the present invention has, as mechanical heat resistance, a performance equal to PMMA while having an excellent surface state of ETFE and thus is useful as a molded member of resin type where a PMMA type material is used. Since it has a surface state of ETFE, it is expected to provide high weather resistance and is suitable for exterior use. Specifically, it is useful e.g. as a resin building material such as gutters, a molded product for signs or markers, or an exterior equipment of an automobile. Further, it may be molded into a film or sheet and thus is useful not only for a back sheet for a solar cell but also for a release film or a highly weather resistant sheet.

This application is a continuation of PCT Application No. PCT/JP2013/084956, filed on Dec. 26, 2013, which is based upon and claims the benefit of priority from Japanese Patent Application No. 2012-284657 filed on Dec. 27, 2012. The contents of those applications are incorporated herein by reference in their entireties.

What is claimed is:

1. A blended polymer which comprises an ethylene/tetrafluoroethylene copolymer and a polymethyl methacrylate, wherein the mass ratio of the ethylene/tetrafluoroethylene copolymer to the total mass of the ethylene/tetrafluoroethylene copolymer and the polymethyl methacrylate, is from 50 to 75%, and which has a microphase-separated structure wherein the continuous phase is the ethylene/tetrafluoroethylene copolymer, and the dispersed phase is the polymethyl methacrylate.

2. The blended polymer according to claim 1, wherein the viscosity-based volume ratio Rη represented by the following formula (1) is smaller than 1:
Rη=(η_{E}/η_{P})×(φ_{P}/φ_{E}) (1)
wherein η_{E} is the melt viscosity of the ethylene/tetrafluoroethylene copolymer at a melting temperature within a range of from 180 to 300° C., η_{P} is the melt viscosity of the polymethyl methacrylate at the same melting temperature as above, φ_{E} is the volume fraction of the ethylene/tetrafluoroethylene copolymer in the blended polymer at the same melting temperature as above, and φ_{P} is the volume fraction of the polymethyl methacrylate in the blended polymer at the same melting temperature as above.

3. The blended polymer according to claim 2, wherein the viscosity-based volume ratio Rη is at least 0.4.

4. The blended polymer according to claim 1, wherein the glass transition temperature of the blended polymer is from 120 to 130° C.

5. The blended polymer according to claim 1, wherein the melt viscosity of the ethylene/tetrafluoroethylene copolymer is from 10 to 3,000 Pa·s at a measuring temperature of 270° C. and a shear rate of 608 s⁻¹.

6. The blended polymer according to claim 1, wherein the ethylene/tetrafluoroethylene copolymer is an ethylene/tetrafluoroethylene copolymer having a molar ratio of (constituent units based on tetrafluoroethylene)/(constituent units based on ethylene) of from 20/80 to 80/20.

7. The blended polymer according to claim 1, wherein the ethylene/tetrafluoroethylene copolymer has units based on a monomer other than ethylene and tetrafluoroethylene, and the ratio of such units is from 0.1 to 10 mol % to all units in the copolymer.

8. The blended polymer according to claim 7, wherein the monomer other than ethylene and tetrafluoroethylene, is a perfluoro-olefin other than tetrafluoroethylene, a polyfluoroalkylethylene or a perfluoro vinyl ether.

9. The blended polymer according to claim 1, wherein the melt viscosity of the polymethyl methacrylate is from 300 to 450 Pa·s at a measuring temperature of 270° C. and a shear rate of 608 s⁻¹.

10. A molded product made of the blended polymer as defined in claim 1.

11. The molded product according to claim 10, which is a film or sheet.

12. A back sheet for a solar cell, which is provided with the film or sheet as defined in claim 11.

13. A method for producing a molded product comprising an ethylene/tetrafluoroethylene copolymer and a polymethyl methacrylate, which comprises melt-kneading an ethylene/tetrafluoroethylene copolymer and a polymethyl methacrylate to form a melt-kneaded product so that the mass ratio of the ethylene/tetrafluoroethylene copolymer to the total mass of the ethylene/tetrafluoroethylene copolymer and the polymethyl methacrylate, would be from 50 to 75%, and the viscosity-based volume ratio Rη represented by the following formula (1) would be smaller than 1, and melt-molding the melt-kneaded product:
Rη=(η_{E}/η_{P})×(φ_{P}/φ_{E}) (1)
wherein ηE is the melt viscosity of the ethylene/tetrafluoroethylene copolymer at a melting temperature within a range of from 180 to 300° C., η_{P} is the melt viscosity of the polymethyl methacrylate at the same melting temperature as above, φ_{E} is the volume fraction of the ethylene/tetrafluoroethylene copolymer in the molded product at the same melting temperature as above, and φ_{P} is the volume fraction of the polymethyl methacrylate in the molded product at the same melting temperature as above.

14. The method for producing a molded product according to claim 13, wherein the melt viscosity of the ethylene/tetrafluoroethylene copolymer is from 10 to 3,000 Pa·s at a measuring temperature of 270° C. and a shear rate of 608 s⁻¹.

15. The method for producing a molded product according to claim 13, wherein the melt viscosity of the polymethyl methacrylate is from 300 to 450 Pa·s at a measuring temperature of 270° C. and a shear rate of 608 s⁻¹.
